(19) United States
(12) Patent Application Publication
(10) Pub. No.: US 2021/0068279 A1
(43) Pub. Date: Mar. 4, 2021

(54) ELECTRONIC DEVICE

(71) Applicant: CAL-COMP BIG DATA, INC., New Taipei City (TW)

(72) Inventors: Tung-Kai Tsai, New Taipei City (TW); Teng-Nan Lo, New Taipei City (TW)

(73) Assignee: CAL-COMP BIG DATA, INC., New Taipei City (TW)

(21) Appl. No.: 16/703,744

(22) Filed: Dec. 4, 2019

(30) Foreign Application Priority Data
Aug. 27, 2019 (CN) 201921402151.4

(51) Int. Cl. H05K 5/02; H05K 5/00; H02G 11/00

(52) U.S. Cl. CPC H05K 5/0217; H02G 11/00; H05K 5/0017; H05K 5/0247

(57) ABSTRACT

Provided is an electronic device including a first body, a second body and a conductor wire. The first body has a first opening. The second body is slidably arranged at the first body and has a second opening. The second body slides between a first position and a second position relative to the first body. The conductor wire includes a fixed section and a movable section. The fixed section is arranged in the second body. The movable section is at least partially arranged in the first body and passes through the first opening to be connected with the fixed section at the second opening. When the second body slides between the first position and the second position, relative positions of the movable section positioned in the first opening and the first opening are unchanged. The electronic device has an attractive appearance and a good protection effect on internal assemblies.

### CROSS-REFERENCE TO RELATED APPLICATION

This application claims the priority benefit of China application serial no. 201921402151.4, filed on Aug. 27, 2019. The entirety of the above-mentioned patent application is hereby incorporated by reference herein and made a part of this specification.

### BACKGROUND

### Technical Field

The disclosure relates to an electronic device, and particularly, to an electronic device with relatively slidable bodies.

### Description of Related Art

Portable electronic devices are popularized for a long time. Slide-up electronic devices still occupy the important status in a consumption market. Generally, two relatively slidable bodies of the slide-up electronic devices are electrically connected with each other through a conductor wire (such as a flat cable), and the conductor wire needs to correspondingly bend or move along with the relative sliding of the two bodies.

FIG. 1 shows a closed state of an existing slide-up electronic device. FIG. 2 shows an unfolded state of the slide-up electronic device in FIG. 1. A body 52 of an existing electronic device 50 has an opening 52a through which a conductor wire 56 passes. In the state shown as FIG. 1, the conductor wire 56 passes through the opening 52a at a right side inner edge 52a1 of the opening 52a. In the state shown as FIG. 2, the conductor wire 56 passes through the opening 52a at a left side inner edge 52a2 of the opening 52a. That is to say, when the body 52 and a body 54 of the electronic device 50 relatively slide between the state shown in the FIG. 1 and the state shown in the FIG. 2, the conductor wire 56 may change its relative position to the opening 52a along with the relative sliding of the body 52 and the body 54, so that the body 52, the body 54 and the conductor wire 56 may be smoothly actuated. In order to enable the conductor wire 56 to move, the opening 52a of the body 52 needs enough width. However, the too big opening 52a exposes an internal space of the body 52 in the state shown as FIG. 2, so that an appearance and a protection effect on internal assemblies are influenced. In order to solve the problem, a shielding structure may need to be added to the body 52 or the body 54, and the manufacturing and assembling cost is increased.

### SUMMARY

The disclosure provides an electronic device, having an attractive appearance and a good protection effect on internal assemblies.

The electronic device provided by the disclosure includes a first body, a second body and a conductor wire. The first body has a first opening. The second body is slidably arranged at the first body and has a second opening. The second body is adapted to slide to a first position relative to the first body to cover the first body, and is adapted to slide to a second position relative to the first body so as to unfold on the first body. The conductor wire includes a fixed section and a movable section. The fixed section is arranged in the second body and extends to the second opening. The movable section is at least partially arranged in the first body and passes through the first opening to be connected with the fixed section at the second opening. When the second body slides between the first position and the second position, relative positions of the movable section positioned in the first opening and the first opening are unchanged.

In one embodiment of the disclosure, the relative positions are relative positions in a sliding direction of the second body.

In one embodiment of the disclosure, when the second body is positioned in the first position, a sub section of the movable section is positioned between the first body and the second body. When the second body is positioned in the second position, the sub section is positioned in the first body. A length of the sub section is not smaller than a sliding distance of the second body between the first position and the second position.

In one embodiment of the disclosure, when the second body slides between the first position and the second position, an inner edge of the first opening pushes and abuts the movable section.

In one embodiment of the disclosure, when the second body is positioned in the first position, the sub section extends between the first opening and the second opening.

In one embodiment of the disclosure, a distance between the first opening and the second opening is reduced along with movement of the second body from the first position to the second position.

In one embodiment of the disclosure, when the second body is in the first position, the sub section does not bend. When the second body is positioned in the second position, the sub section bends.

In one embodiment of the disclosure, the movable section has a bending part in the first body. When the second body moves from the first position to the second position in a first direction, the bending part moves relative to the first body in a second direction opposite to the first direction.

In one embodiment of the disclosure, the movable section has two mutually parallel extending parts in the first body. The bending part is connected between the two extending parts. A length of each of the extending parts is increased along with movement of the bending part in the second direction.

In one embodiment of the disclosure, the conductor wire is a flat cable.

In one embodiment of the disclosure, the first body has a display surface. When the second body is positioned in the first position, the display surface is covered by the second body. When the second body is positioned in the second position, the display surface is exposed by the second body.

Based on the above, in the electronic device of the disclosure, when the first body and the second body relatively slide, the relative positions of the conductor wire positioned in the first opening of the first body and the first opening are unchanged, so that the first opening does not need a big width for the movement of the movable section of the conductor wire. Therefore, when the first body and the second body are relatively unfolded, the appearance and the protection effect on internal assemblies cannot be influenced by the too big opening of the body. The additional arrangement of a shielding structure for the first body or the second body is not needed, so that the manufacturing and assembly cost of the electronic device is reduced.

In order to make the aforementioned and other objectives and advantages of the disclosure comprehensible, embodiments accompanied with figures are described in detail below.

### BRIEF DESCRIPTION OF THE DRAWINGS

FIG. 1 shows a closed state of an existing slide-up electronic device.

FIG. 2 shows an unfolded state of the slide-up electronic device in FIG. 1.

FIG. 3 is a stereogram of an electronic device in one embodiment of the disclosure.

FIG. 4 shows that a second body is unfolded relative to a first body in FIG. 3.

FIG. 5A and FIG. 5B are exploded views of the electronic device in FIG. 3 respectively in different visual angles.

FIG. 6 is a sectional view of the electronic device in FIG. 3.

FIG. 7 is a sectional view of the electronic device in FIG. 4.

FIG. 8 and FIG. 9 respectively show conductor wires in FIG. 6 and FIG. 7.

FIG. 10 is a partial enlarged drawing of the electronic device in FIG. 7.

### DESCRIPTION OF THE EMBODIMENTS

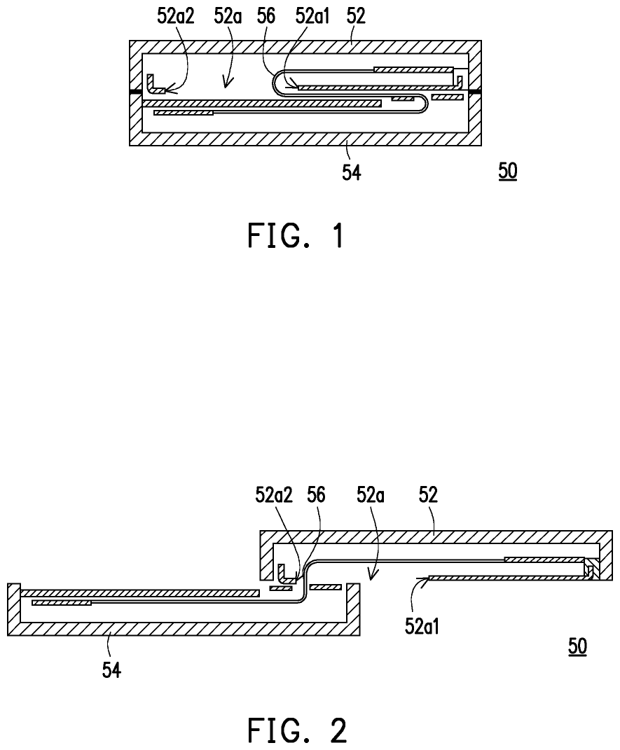

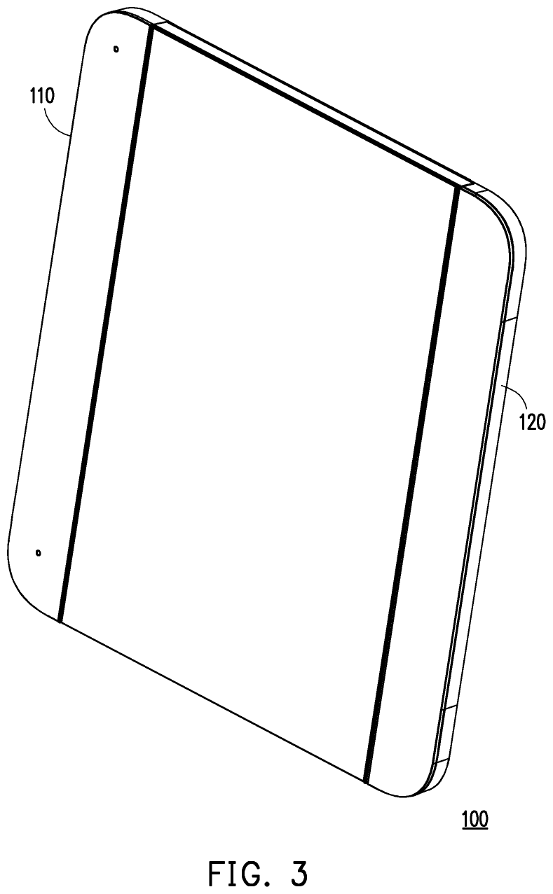

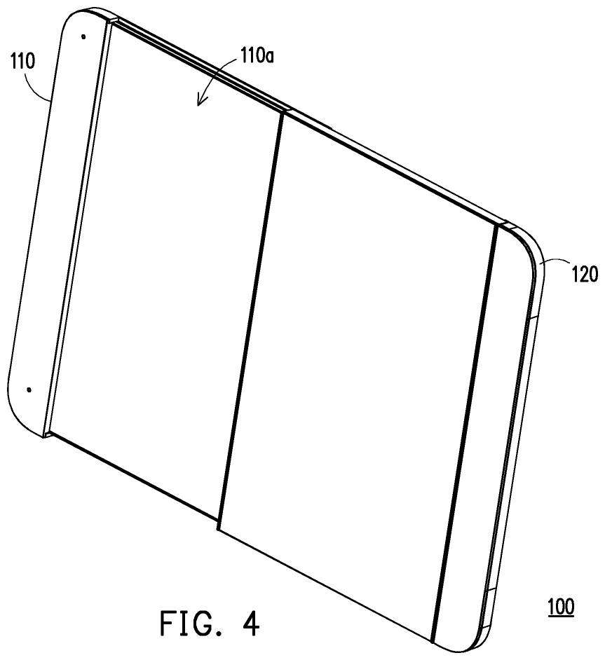

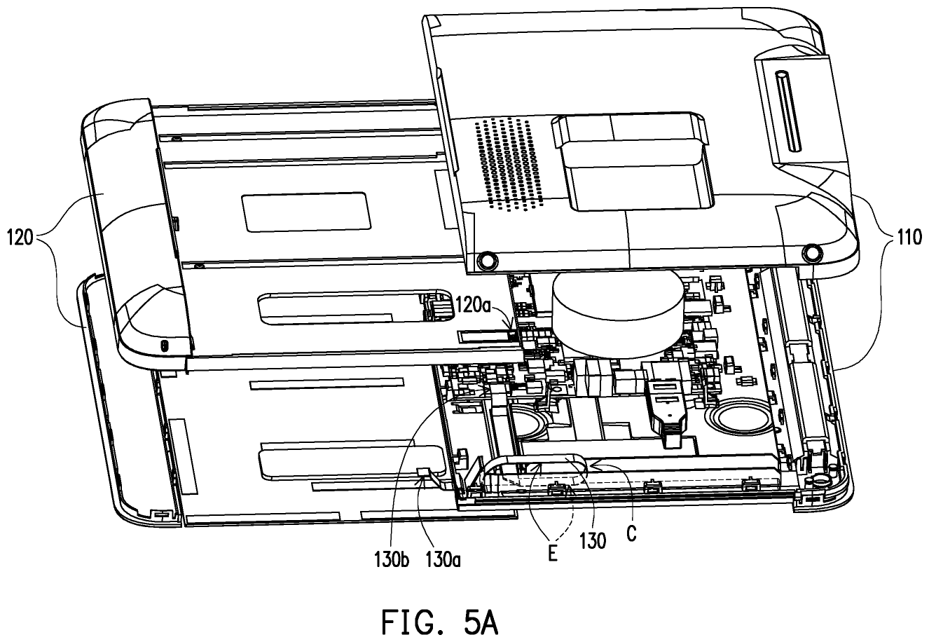

FIG. 3 is a stereogram of an electronic device in one embodiment of the disclosure. FIG. 4 shows that a second body is unfolded relative to a first body in FIG. 3. Referring to FIG. 3 and FIG. 4, an electronic device 100 of the present embodiment includes a first body 110 and a second body 120. The first body 110, for example, has a display surface 110a, and is a tablet personal computer or a device similar to the tablet personal computer in function. The second body 120 is slidably arranged at the first body 110, is adapted to slide to a first position shown as FIG. 1 relative to the first body 110 to cover a display surface 110a of the first body 110, and is also adapted to slide to a second position shown as FIG. 2 relative to the first body 110 to unfold on the first body 110 and to expose the display surface 110a of the first body 110.

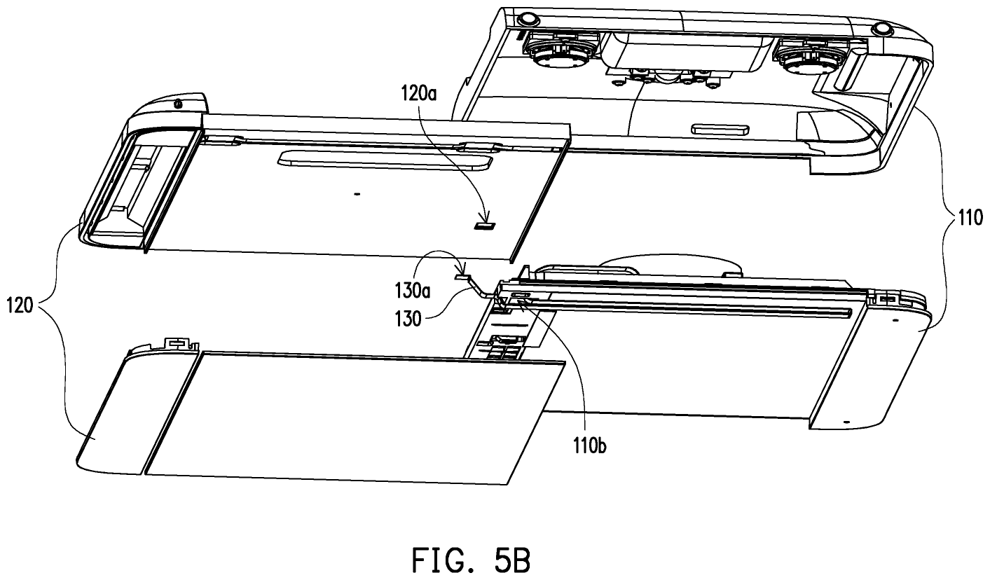

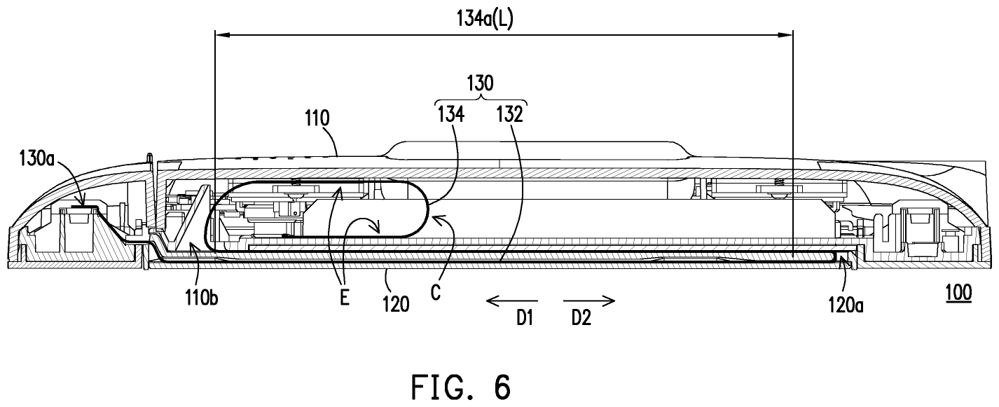

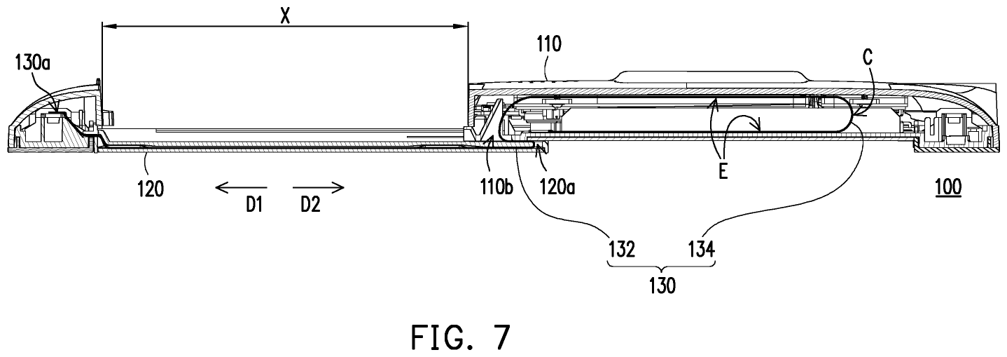

FIG. 5A and FIG. 5B are exploded views of the electronic device in FIG. 3 respectively in different visual angles. FIG. 6 is a sectional view of the electronic device in FIG. 3. FIG. 7 is a sectional view of the electronic device in FIG. 4. Referring to FIG. 5A to FIG. 7, the electronic device 100 of the present embodiment includes a conductor wire 130. The conductor wire 130 is, for example, a flat cable, and is configured to electrically connect the first body 110 and the second body 120. The conductor wire is configured to provide any one or both of signal transmission and power supply. The conductor wire 130 may correspondingly bend or move along with the relative sliding of the first body 110 and the second body 120. The conductor wire 130, for example, is respectively connected with electronic assemblies in the first body 110 and the second body 120 through its two opposite tail ends 130a and 130b. The electronic assembly in the second body 120, for example, is an illumination light source or an information display panel.

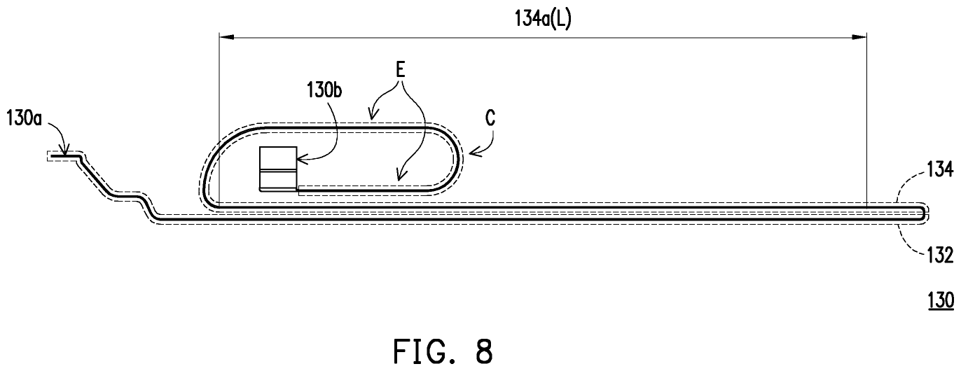

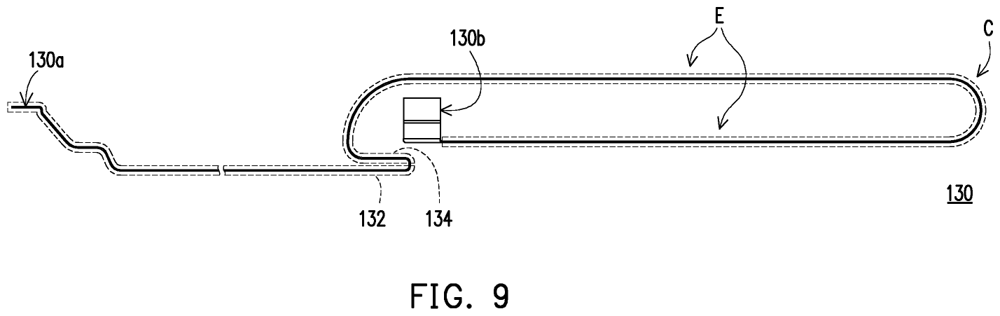

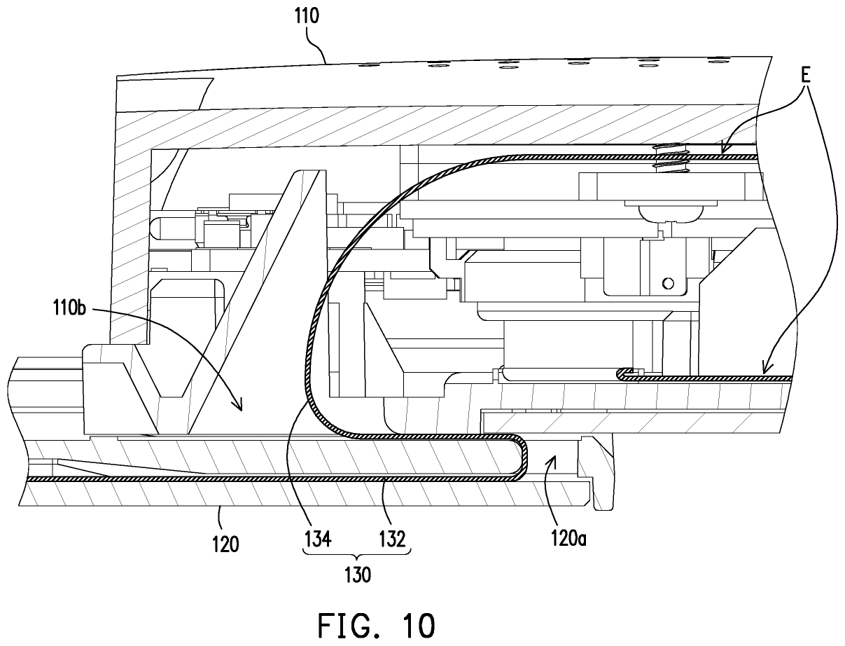

FIG. 8 and FIG. 9 respectively show conductor wires in FIG. 6 and FIG. 7. FIG. 10 is a partial enlarged drawing of the electronic device in FIG. 7. The conductor wire 130 of the present embodiment includes a fixed section 132 and a movable section 134. In FIG. 8 and FIG. 9, the ranges of the fixed section 132 and the movable section 134 are specifically marked. As shown in FIG. 10, the first body 110 has a first opening 110b, and the second body has a second opening 120a. The fixed section 132 is fixed in the second body 120, and extends to the second opening 120a of the second body 120. The movable section 134 is at least partially arranged in the first body 110 and passes through the first opening 110b of the first body 110 to be connected with the fixed section 132 at the second opening 120a. When the second body 120 slides between the first position and the second position in a first direction D1 or in a second direction D2 opposite to the first direction D1, relative positions of the movable section 134 positioned in the first opening 110b and the first opening 110b in a sliding direction of the second body 120 are unchanged. It should be noted that when the second body 120 slides relative to the first body 110, at the first opening 110b, the movable section 134 of the conductor wire 130 may move in a way of passing through the first opening 110b in a vertical direction of FIG. 6 and FIG. 7. Thus, it may be understood that the above-mentioned “movable section 134 positioned in the first opening 110b” refers to a plurality of continuous parts of the movable section 134. These parts sequentially pass through the first opening 110b at a plurality of continuous time points. The above-mentioned sentence that “the relative position to the first opening 110b is unchanged” refers to that the positions of these parts of the movable section 134 in the first opening 110b are all identical.

Under the condition of this configuration and actuating mode, the first opening 110b does not need a great width for the movement of the movable section 134 of the conductor wire 130. Therefore, when the first body 110 and the second body 120 are relatively unfolded as shown in FIG. 4 and FIG. 6, and the condition that the appearance and the protection effects on the internal assemblies are influenced by a too big opening of the body is avoided. The additional arrangement of a shielding structure for the first body 110 or the second body 120 is not needed, so that the manufacturing and assembling cost of the electronic device 100 is reduced.

In the present embodiment, when the second body 120 shown as FIG. 6 is positioned in the first position, a sub section 134a (marked in FIG. 6 and FIG. 8) of the movable section 134 extends between the first opening 110b and the second opening 120a in a non-bending way, and is positioned between the first body 110 and the second body 120 to be hidden. A distance between the first opening 110b and the second opening 120a is reduced along with the movement of the second body 120 from the first position to the second position. When the second body 120 is positioned in the second position as shown in FIG. 7, the sub section 134a of the movable section 134 is coiled in the first body 110 in a bent way to be hidden. The length L of the sub section 134a is not smaller than a sliding distance X (marked in FIG. 7) of the second body 120 between the first position and the second position. Therefore, in the sliding process of the second body 120, even if the movable section 134 of the conductor wire 130 does not move in the first opening 110b of the first body 110 in the first direction D1 or the second direction D2, the first body 110, the second body 120 and the conductor wire 130 may be smoothly actuated through the bending and the movement of the sub section 134a with the enough length.

An actuation mode of the conductor wire 130 of the present embodiment is specially illustrated hereafter.

When the second body 120 slides between the first position and the second position. The first body 110, for example, pushes and abuts the movable section 134 of the conductor wire 130 through an inner edge of the first opening 110b, so that the conductor wire 130 may smoothly bend and move between the states shown in FIG. 6 and FIG. 7 along with the sliding of the second body 120. Additionally, the movable section 134 of the conductor wire 130 has a bending part C and two mutually parallel extending parts E in the first body 110. The bending part C is connected with the two extending parts E. When the second body 120 moves from the first position to the second position in the first direction D1, the bending part C of the conductor wire 130, shown as FIG. 6 and FIG. 7, moves relative to the first body 110 in the second direction D2 opposite to the first direction D1. On the contrary, when the second body 120 moves from the second position to the first position in the second direction D2, the bending part C of the conductor wire 130, shown as FIG. 7 to FIG. 6, moves relative to the first body 110 in the first direction D1 opposite to the second direction D2. The length of each extending part E is increased along with the movement of the bending part C in the second direction D2, and is increased along with the movement of the bending part C in the first direction D1. In other embodiments, the movable section 134 of the conductor wire 130 may be movably arranged at the second body 120 in other proper modes, and this is not limited by the disclosure.

Based on the above, in the electronic device of the disclosure, when the first body and the second body relatively slide, the relative positions of the conductor wire positioned in the first opening of the first body and the first opening are unchanged, so that the first opening does not need the great width for the movement of the movable section of the conductor wire. Therefore, when the first body and the second body are relatively unfolded, the condition that the appearance and the protection effect on the internal assemblies are influenced by a too big opening of the body is avoided. The additional arrangement of the shielding structure for the first body or the second body is not needed, so that the manufacturing and assembling cost of the electronic device is reduced.

It should be finally noted that the above embodiments are merely intended for describing the technical solutions of the disclosure other than limiting the disclosure. Although the disclosure is described in detail with reference to the foregoing embodiments, persons of ordinary skill in the art should understand that they can still make modifications to the technical solutions described in the foregoing embodiments or make equivalent substitutions to some technical features thereof, without departing from scope of the technical solutions of the embodiments of the disclosure.

What is claimed is:

1. An electronic device, comprising:
a first body, comprising a first opening;
a second body, slidably arranged at the first body and comprising a second opening, wherein the second body is adapted to slide to a first position relative to the first body so as to cover the first body, and is adapted to slide to a second position relative to the first body so as to unfold on the first body; and
a conductor wire, comprising a fixed section and a movable section, wherein the fixed section is arranged in the second body and extends to the second opening, and the movable section is at least partially arranged in the first body and passes through the first opening to be connected with the fixed section at the second opening, and
when the second body slides between the first position and the second position, relative positions of the movable section positioned in the first opening and the first opening are unchanged, and
when the second body slides between the first position and the second position, an inner edge of the first opening pushes and abuts the movable section.

2. The electronic device according to claim 1, wherein the relative positions are relative positions in a sliding direction of the second body.

3. The electronic device according to claim 1, wherein when the second body is positioned in the first position, a sub section of the movable section is positioned between the first body and the second body, when the second body is positioned in the second position, the sub section is positioned in the first body, and a length of the sub section is not smaller than a sliding distance of the second body between the first position and the second position.

4. The electronic device according to claim 3, wherein when the second body is positioned in the first position, the sub section extends between the first opening and the second opening.

5. The electronic device according to claim 3, wherein when the second body is positioned in the first position, the sub section does not bend, and when the second body is positioned in the second position, the sub section bends.

6. (canceled)

7. The electronic device according to claim 1, wherein a distance between the first opening and the second opening is reduced along with movement of the second body from the first position to the second position.

8. The electronic device according to claim 1, wherein the movable section comprises a bending part in the first body, and when the second body moves from the first position to the second position in a first direction, the bending part moves relative to the first body in a second direction opposite to the first direction.

9. The electronic device according to claim 8, wherein the movable section comprises two mutually parallel extending parts in the first body, the bending part is connected between the two extending parts, and a length of each of the extending parts is increased along with movement of the bending part in the second direction.

10. The electronic device according to claim 1, wherein the conductor wire is a flat cable.

11. The electronic device according to claim 1, wherein the first body comprises a display surface, and when the second body is positioned in the first position, the display surface is covered by the second body, and when the second body is in the second position, the display surface is exposed by the second body.
